(19) United States
(12) Patent Application Publication
(10) Pub. No.: US 2010/0078824 A1
(43) Pub. Date: Apr. 1, 2010

(54) Method for forming three-dimensional structure, method for manufacturing semiconductor device, and semiconductor device

(75) Inventor: Kazuaki Okamori, Kanagawa (JP)

Correspondence Address: AKERMAN SENTERFITT, 8100 BOONE BOULEVARD, SUITE 700, VIENNA, VA, 22182-2683, US

(73) Assignee: FUJIFILM Corporation, Tokyo (JP)

(21) Appl. No.: 12/585,875

(22) Filed: Sep. 28, 2009

(30) Foreign Application Priority Data
Sep. 30, 2008 (JP) 2008-254195

(51) Int. Cl. H01L 21/768; H01L 21/50; H01L 23/482

(52) U.S. Cl. 257/773; 438/674; 438/121; 257/E21.582; 257/E21.499; 257/E23.012

(57) ABSTRACT

A method for forming a three-dimensional structure comprises: a first step of dropping a liquid material containing a structure-forming material and a solvent onto a structure forming surface; and a second step of drying at least a part of the solvent in the dropped liquid material to form a deposit layer on the structure forming surface, wherein the first step and the second step are repeated while a dropping position of the liquid material is shifted such that a next droplet of the liquid material is dropped onto the deposit layer formed of the previously-dropped liquid material to repeatedly accumulate the deposit layers on the structure forming surface, thereby forming a three-dimensional structure having at least one inclination portion inclined with respect to the structure forming surface.

### BACKGROUND OF THE INVENTION

The present invention relates to a method for forming a three-dimensional structure using a liquid material in which a structure-forming material is dispersed or dissolved, a method for manufacturing a semiconductor device, and a semiconductor device. More specifically, the present invention relates to a method for forming a three-dimensional structure without making supporting bases.

A conventional method for forming fine wiring patterns utilizes an inkjet technique. In the method using the inkjet technique, conductive fine-particle paste in which conductive fine-particles having a particle diameter of 100 nm or smaller are dispersed is ejected onto a substrate to form a wiring pattern, and the wiring pattern is then sintered to develop conductive properties, thereby forming a conductor circuit.

However, the method utilizing the inkjet technique has a difficulty in forming a three-dimensional wiring, for example, on a stepped substrate or onto an upper electrode of a semiconductor chip provided on a substrate. In view of the difficulty, several methods for forming three-dimensional wiring have been proposed.

WO 2003/084297, for example, discloses a method for manufacturing a wiring structure by applying a paste of conductive fine particles on a three dimensional, electrically-insulating layer called “cell” through the inkjet technique or the dispenser, thereby forming connection wiring.

WO 2003/084297 further discloses two alternative processes in the method for manufacturing a wiring structure, that is, forming “cells” on a substrate, or disposing on a substrate “cells” which are preliminarily prepared.

However, the method for manufacturing a wiring structure disclosed in WO 2003/084297 can form a three-dimensional wiring but requires making “cells” (insulating layer), i.e., bases to support connection wiring. While the two alternative processes for making these “cells,” i.e., forming “cells” on a substrate or disposing on a substrate “cells” which are preliminarily prepared, have been disclosed, either of the process requires additional steps in the manufacturing method and hence lowers its productivity.

In addition, the method including a process of forming “cells” would involve a problem of wire breaking due to a difference in wettability between two different materials of the cells and the conductive fine particle paste, or to a minute difference in levels among the “cells.”

### SUMMARY OF THE INVENTION

The present invention has an object to solve the above-described problem of the conventional technology and to provide a method for forming a three-dimensional structure with a fewer processes.

In addition, the present invention also has another object to provide a method for manufacturing a semiconductor device in which unfailing three-dimensional wiring is achieved by using the thus-obtained three-dimensional structure and to provide a semiconductor device in which unfailing three-dimensional wiring is achieved.

A method for forming a three-dimensional structure according to the invention comprises:

a first step of dropping a liquid material containing a structure-forming material and a solvent onto a structure forming surface; and

a second step of drying at least a part of the solvent in the dropped liquid material to form a deposit layer on the structure forming surface,

wherein the first step and the second step are repeated while a dropping position of the liquid material is shifted such that a next droplet of the liquid material is dropped onto the deposit layer formed of the previously-dropped liquid material to repeatedly accumulate the deposit layers on the structure forming surface, thereby forming a three-dimensional structure having at least one inclination portion inclined with respect to the structure forming surface.

A method for manufacturing a semiconductor device according to the invention comprises:

a step of mounting at least one semiconductor chip on a surface of a substrate having at least one first electrode thereon, each semiconductor chip being provided with at least one second electrode; and

a step of forming wiring between the at least one second electrode of each semiconductor chip and the at least one first electrode by the above method for forming a three-dimensional structure.

A semiconductor device according to the invention manufactured by the above method for manufacturing a semiconductor device.

### BRIEF DESCRIPTION OF THE DRAWINGS

FIG. 1 is a block diagram showing an apparatus that realizes a method for forming a three-dimensional structure according to a first embodiment of the present invention.

FIGS. 2A to 2F are diagrams showing processes of the method for forming a three-dimensional structure in order according to the first embodiment.

FIGS. 3A to 3D are diagrams showing details of the main parts in the processes of the method for forming a three-dimensional structure in order according to the first embodiment.

FIG. 4 is a side view showing a three-dimensional structure formed in an exemplary variation of the first embodiment.

FIG. 5 is a side view showing a three-dimensional structure formed in a second embodiment of the present invention.

FIG. 6 is a side view showing a semiconductor device manufactured in the second embodiment.

FIG. 7 is a side view showing a semiconductor device manufactured in a third embodiment of the present invention.

FIG. 8 is a graph showing a relationship between a shift amount of a droplet arrival position and an inclination angle of an inclined wire in Example 1.

FIG. 9 is a graph showing a relationship between a shift amount of a droplet arrival position and an inclination angle of an inclined wire in Example 2.

FIG. 10 shows a wiring obtained in Example 3.

### DETAILED DESCRIPTION OF THE INVENTION

On the following pages, the method for forming a three-dimensional structure, the method for manufacturing a semiconductor device, and a semiconductor according to the present invention are described in details based on the preferable embodiments shown in the accompanying drawings.

### First Embodiment

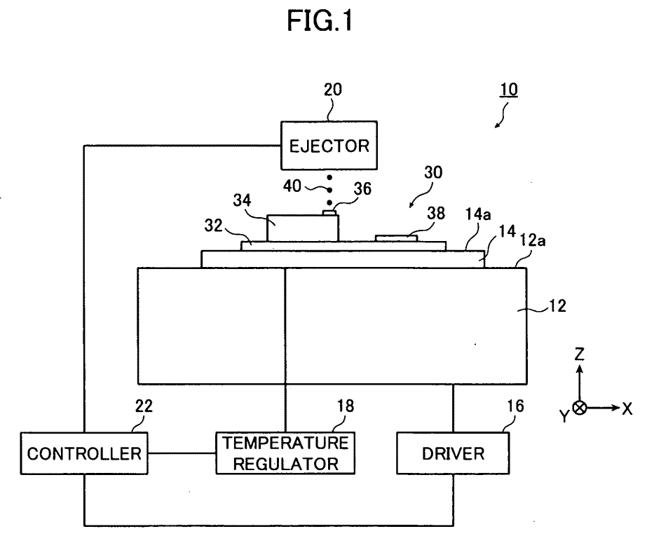

FIG. 1 is a block diagram showing an apparatus 10 that realizes the method for forming a three-dimensional structure according to a first embodiment of the present invention.

The apparatus 10 forms a three-dimensional structure without making supporting bases. In particular, for example, the apparatus forms an inclined wire or wiring extending three-dimensionally on a substrate, and comprises a stage 12, a heater 14, a driver 16, a temperature regulator 18, an ejector 20, and a controller 22.

The heater 14 in a planar shape is provided on a surface 12a of the stage 12. The stage 12 is arranged such that its surface 12a is horizontal. To the stage 12, connected is a moving mechanism (not shown) which moves the stage 12 in three directions, the directions X and Y both parallel to the surface 12a and the direction Z perpendicular to the surface 12a.

The driver 16 drives the moving mechanism to move the stage 12 in the direction X, direction Y and direction Z.

The heater 14 may be, for instance, a carbon heater or a silicon heater. The heater 14 is connected to the temperature regulator 18, by which the temperature of the heater 14 is regulated.

A member to be processed 30 on which a three-dimensional structure is formed is placed on a surface 14a of the heater 14. In this embodiment, the member to be processed 30 is a semifinished product for a semiconductor device and includes a substrate 32, a semiconductor chip 34 and electrodes 36, 38.

The heater 14 typically heats the member to be processed 30 to expedite drying of a liquid material which has been dropped on the member 30. By promoting volatilization of the dropped liquid material, the liquid material can be deposited even if the liquid material is ejected at a high frequency. In addition, with the expedited drying, the dropped liquid material can be kept away from hanging to thereby improve accuracy in formation of a three-dimensional structure.

Here, the temperature of the member to be processed 30 heated by the heater 14 (heating-temperature of the member 30) is preferably set to at least a temperature at which all solvent in the liquid material arriving at a target can be dried within an interval of liquid material ejection.

With a low heating-temperature of the member to be processed 30 by the heater 14, an amount of the liquid material being dropped exceeds an amount of evaporation of the solvent; an inclined wire in the three-dimensional structure would become thicker toward its end, and at the same time the more liquid material would be hanging, resulting in unstable formation of the inclined wire.

The ejector 20 drops the liquid material (ink) 40 in which a structure-forming material is dispersed or dissolved onto a surface of the member to be processed 30 (a structure forming surface) where a three-dimensional structure is formed and comprises a positioning mechanism (not shown) for adjusting a liquid-dropping position.

The structure of the ejector 20 is not particularly limited as long as the ejector 20 can drop the liquid material (ink) 40 in which the structure-forming material is dispersed or dissolved. The ejector 20 preferably adopts an inkjet head. In case an inkjet head is used for the ejector 20, the ejection amount of liquid material, the ejection frequency, and the arrival position of the ejected liquid material can be accurately controlled.

The inkjet head can be of any type such as a piezoelectric type, a thermal type, an electrostatic actuator type, or an electrostatic attraction type.

Or, the ejector 20 may be a dispenser. A dispenser is normally capable of ejecting a larger amount of liquid than an inkjet head and hence is capable of forming a larger three-dimensional structure.

The structure-forming material is preferably fine particles of a metal, an oxide thereof, or an alloy thereof. Examples of the metal include gold, silver, copper, platinum, nickel, palladium, and tin. And, fine particles of the metal, of the oxide thereof, or of the alloy thereof preferably have a particle diameter of 10 nm or smaller.

Conductive properties will be imparted to the structure-forming material made of fine particles of the above-described metal, the oxide thereof or the alloy thereof once it is subjected to a sintering process.

In the present invention, the structure-forming material may be another material having conductive properties such as a conductive polymer material.

The liquid material 40 in which the structure-forming material is dispersed or dissolved can be exemplified by NSP-J (trade name) manufactured by Harima Chemicals, Inc.

A dispersion media or a solvent to which the structure-forming material is dispersed or dissolved can be not only water but also an alcohol such as methanol, ethanol, propanol, or butanol; a hydrocarbon compound such as n-heptane, n-octane, decane, tetradecane, toluene, xylene, cymene, durene, indene, dipentene, tetrahydronaphthalene, decahydronaphtalene, or cyclohexylbenzene; an ether compound such as ethylene glycol dimethyl ether, ethylene glycol diethyl ether, ethylene glycol methylethyl ether, diethylene glycol dimethyl ether, diethylene glycol diethyl ether, diethylene glycol methylethyl ether, 1,2-dimethoxyethane, bis(2-methoxyethyl)ether, or p-dioxane; or a polar compound such as propylene carbonate, γ-butyrolactone, N-methyl-2-pyrolidone, dimethylformamide, dimethylsulfoxide, or cyclohexanone. Among these, water, an alcohol, a hydrocarbon compound, and an ether compound are preferable, and, particularly, water and a hydrocarbon compound are more preferable, in terms of dispersibility of the fine particles and stability of dispersion liquid as well as applicability to a variety of liquid ejection techniques. These dispersion medium and solvents can be used singly or as mixture of two or more thereof.

The controller 22 is connected to and controls the ejector 20, the driver 16 and the temperature regulator 18. Under the control by the controller 22, the ejector 20 and the stage 12 are moved to be positioned at which the liquid material 40 is dropped from the ejector 20, the temperature regulator 18 raises the temperature of the heater 14 to heat the member to be processed 30 to a predetermined temperature, and the ejector 20 drops the liquid material 40.

In the apparatus 10 for forming a three-dimensional structure, the stage 12 may include a heater for the sintering process. For such a sintering heater, an infrared lamp or the like that is good for rapid heating can be used.

In addition, a sintering furnace may be provided in order to sinter the formed three-dimensional structure. In this case, preferably provided is a transporting means for transporting the three-dimensional structure from the stage 12 to the sintering furnace.

Next, the method for forming a three-dimensional structure by using the apparatus 10 will be described. In this embodiment, wiring between electrodes in a semiconductor device is formed as a three-dimensional structure.

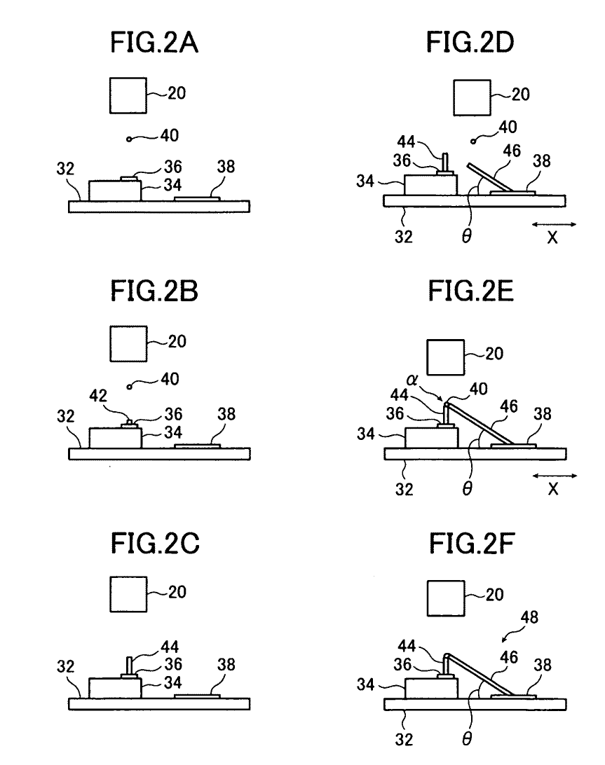

As shown in FIG. 2A, a semiconductor chip 34 is placed and fixed onto a substrate 32. On an upper surface of the semiconductor chip 34, an upper electrode 36 is provided, while another electrode 38 is provided on the substrate 32. In this embodiment, wiring is formed to electrically connect the upper electrode 36 on the semiconductor chip 34 and the electrode 38 on the substrate 32. The semiconductor chip 34 becomes workable with this wiring.

The substrate 32 may be made of a planar member of various materials including a glass substrate, a ceramic substrate, and a plastic substrate.

In addition, the substrate 32 may be a flexible film material, which can be bent. Various kinds of plastic films can be used as the substrate 32, and examples thereof are films of polyethylene terephthalate, polybutylene terephthalate, polycycloolefin, biaxially-oriented polypropylene, polycarbonate, polyamide, polyvinyl chloride, methacryl styrene resin, polyimide, silicone resin, and fluorine resin.

And, examples of the semiconductor chip 34 include an IC chip, a memory device (a flush memory, SRAM), an LD element, and an LED element.

This embodiment uses a liquid material of an ink 40 made of a solvent in which fine particles of a metal are dispersed; the ink 40 is ejected from the ejector 20 onto the substrate 32 to form wiring.

In the method for forming a three-dimensional structure according to this embodiment, the ejector 20 first ejects the ink 40 onto the upper electrode 36. At this time, the temperature regulator 18 regulates a temperature of the heater 14, which is arranged beneath the substrate 32, to a predetermined temperature so as to maintain the temperature of the substrate 32 at a certain temperature. The temperature of the substrate 32 is regulated to allow a part of or all of the solvent in the ink 40 being ejected by the ejector 20 and arriving at the substrate 32 to volatilize before the next droplet of the ink 40 arrives thereat.

Accordingly, the ink 40 which has been preliminarily ejected becomes a deposit layer (dried body) 42 as shown in FIG. 2B before the next droplet of the ink 40 arrives thereat so that the droplet layer 42 is prevented from spreading, resulting in further deposition of metal particles on the deposit layer 42. By repeating ejection of the ink 40 onto the deposit layer 42 in this manner, a vertical wire 44 extending vertically upward on the upper electrode 36 can be formed due to deposition of metal particles, as shown in FIG. 2C.

In formation of the vertical wire 44, the temperature of the substrate 32 is regulated by the heater 14 and the temperature regulator 18 such that solvent in the ink 40 ejected from the ejector 20 volatilizes more quickly than the ink 40 fully runs and spreads upon arrival on the substrate 32. Hence, ejection of the ink 40 is repeated while the ejection frequency is adjusted in such a manner that the ink 40 of the subsequent ejection arrives at the deposit layer 42 after the ink 40 of the preceding ejection dries, forming a columnar wire having a diameter almost same as that of the ejected droplet dot.

Then, an inclined wire 46 is formed on the electrode 38. To do so, the stage 12 is moved by the driver 16 so as to shift the arrival position of the ink 40 ejected by the ejector 20 as shown in FIG. 2D.

Formation of the inclined wire 46 on the electrode 38 includes dropping the ink 40 in which the structure-forming material is dispersed or dissolved onto the electrode 38, drying a part of or all of solvent in the ink 40 to form a deposit layer, thereafter moving the stage 12 on which the substrate 32 is mounted in the direction X (direction parallel to the surface of the substrate 32) by the driver 16 to slightly shift a positional relationship between the ejector 20 and the substrate 32 in the direction X, dropping the next droplet of the ink 40 on the deposit layer, and drying solvent in the ink 40. In this way, deposition of the deposit layer is repeated while the stage 12 is moved, and hence the inclined wire 46 three-dimensionally extending at a predetermined inclination angle θ with respect to the substrate 32 is formed.

As the deposition of the deposit layer is repeated, the inclined wire 46 gradually extends toward the vertical wire 44 formed on the upper electrode 36 while being kept at the predetermined inclination angle θ. Finally, as shown in FIG. 2E, the ink 40 is dropped to a joining portion a between the vertical wire 44 and the inclined wire 46; as the dropped ink 40 dries to form a deposit layer at the portion, the vertical wire 44 and the inclined wire 46 are joined to each other so as to form wiring 48 connecting the upper electrode 36 and the electrode 38 as shown in FIG. 2F.

Then, the wiring 48 thus formed is subjected to sintering for a certain period of time to allow metal particles therein to fuse with each other, and hence obtains conductive properties. As a result, the upper electrode 36 and the electrode 38 are electrically connected.

In this embodiment, the wiring 48 is sintered to become a sintered body in the end. In addition, a three-dimensional structure other than wiring may also be formed as a sintered body in this embodiment.

Since the wiring 48 is subjected to a sintering process in the end in this embodiment, the vertical wire 44 and the inclined wire 46 are preferably formed to be longer by a length which would compensate heat shrinkage undergone in the sintering process.

During formation of the inclined wire 46 in this embodiment, the heating temperature of the substrate 32 and the ejection frequency of the ink 40 are adjusted while the stage 12 is moved in the direction X to gradually shift an arrival position of the ink 40 with respect to the substrate 32 in the direction X, thereby relatively shifting the ejector 20 and the substrate 32.

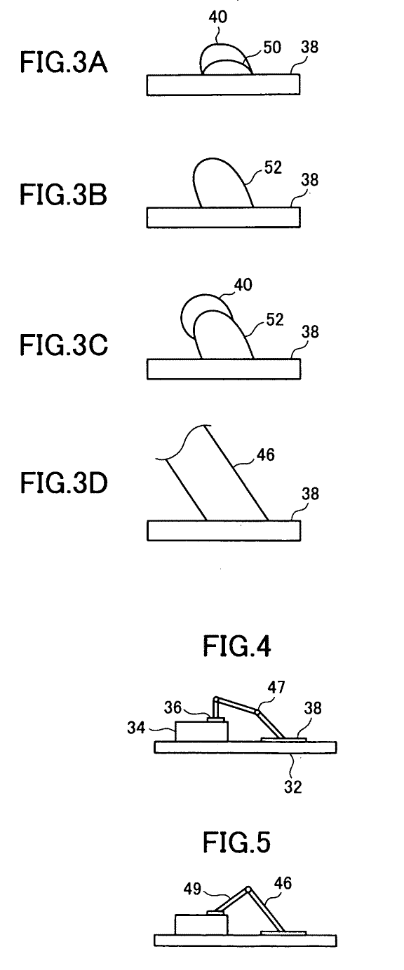

Here, the ink 40 is ejected onto a deposit layer (dried body) 50 made of the dried ink 40 as the substrate 32 is slightly shifted in the direction X as shown in FIG. 3A and hence arrives at a position displaced to one side. Thus, a deposit layer 52 that has been dried also leans to one side as illustrated in FIG. 3B.

Next, the ejector 20 and the substrate 32 are further relatively shifted, and another droplet of the ink 40 is ejected onto the deposit layer 52 as shown in FIG. 3C. Here, again, an arrival position of the ink 40 is displaced to the side.

These processes of ejecting the ink 40 and drying it to deposit the deposit layer 52 as described above are repeated to finally form, without making supporting bases, the inclined wire 46 which is three-dimensionally extending at a predetermined inclination angle with respect to the surface of the substrate 32, the angle depending on displacement of arrival positions of the ink 40.

In this embodiment, since no supporting bases made of an insulating resin or the like need to be prepared, a risk of wire breaking due to a difference in wettability between the supporting base material and the metal fine particles of the ink 40 or a minute difference in levels among the supporting bases can be removed.

Note that the inclination angle θ of the inclined wire 46 can be controlled by a shift amount of the arrival position of the ink, as described later.

Furthermore, the inclination angle θ of the inclined wire 46 is preferably 30° or larger. If the inclination angle θ of the inclined wire 46 is smaller than 30°, a shift amount of the arrival position of the ink 40 would be too large, lowering the manufacturing yield.

And, the inclined wire is not limited to one having a certain inclination angle. The inclined wire may have one or more bending portions. In particular, as shown in FIG. 4, the inclined wire may comprise at least two straight portions having different inclination angles with forming a bending portion 47 therebetween. The wire of this structure can be formed by varying shift amounts of the arrival position of the ink 40 during forming the inclination wire.

### Second Embodiment

While the wiring 48 comprises the vertical wire 44 and the inclined wire 46 in the first embodiment, this is not the sole case and the wiring may be in an arch shape as illustrated in FIG. 5, for example, in which the vertical wire 44 is changed to be an inclined wire 49, and this inclined wire 49 and the inclined wire 46 are joined at their ends.

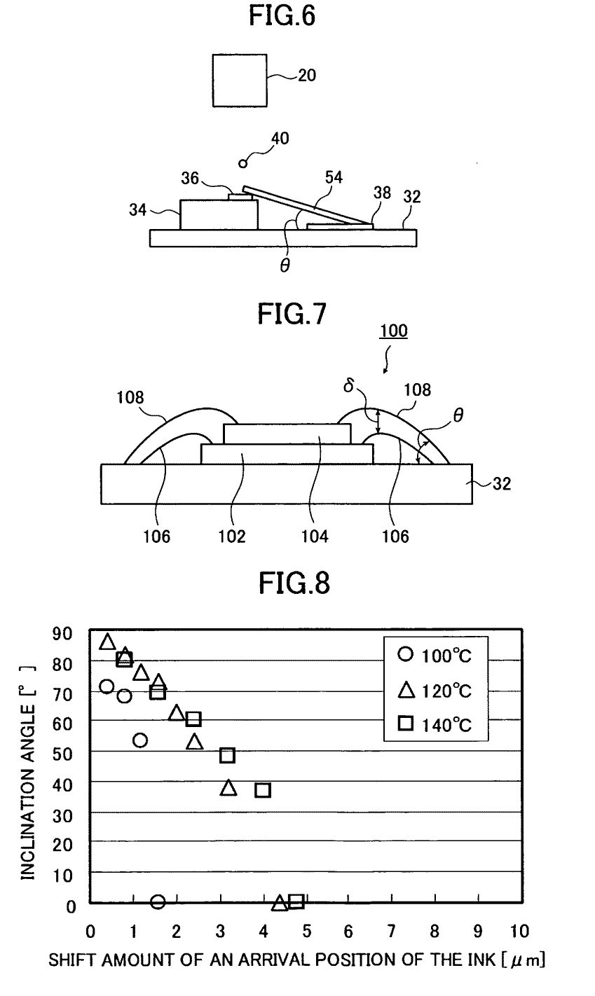

Also, the upper electrode 36 on the semiconductor chip 34 and the electrode 38 on the substrate 32 can be electrically connected via linear wiring 54 as shown in FIG. 6.

### Third Embodiment

The method for forming a three-dimensional structure of the present invention can be also used to manufacture a semiconductor device 100 shown in FIG. 7.

The semiconductor device 100 is a chip-on-chip structure; on the substrate 32, a first semiconductor chip 102 and a second semiconductor chip 104 are superposed sequentially.

In the semiconductor device 100, upper electrodes on the first semiconductor chip 102 and first electrodes on the substrate 32 are connected through first wirings 106, while upper electrodes on the second semiconductor chip 104 and second electrodes on the substrate 32 are connected through second wirings 108.

The first semiconductor chip 102 and the second semiconductor chip 104 are, for example, IC chips or memory devices (such as a flush memory and SRAM).

In order to manufacture the semiconductor device 100, similarly in the first embodiment described above, the ink 40 is dropped while the ejector 20 and the substrate 32 are relatively moved to shift the arrival position of the ink 40, to thereby form the first wirings 106 and the second wirings 108.

Since simply the ink 40 is dropped while arrival position of the ink being shifted in this embodiment, only a just space for wiring is sufficient and it does not require additional spaces for wedges or capillaries which have been required in a conventional wire bonding technique. Hence, wiring can be formed on the substrate 32 which is smaller than a substrate in the conventional technique, realizing reduction in size of the semiconductor device 100 and, in addition, the higher packaging density of the semiconductor device 100.

Moreover, since this embodiment of the present invention requires no capillaries, wirings with narrower interspaces can be formed on the substrate surface. In addition, by using an inkjet head, varying of an interspace δ between, for example, the first wiring 106 and the second wiring 108 can be small when wirings are formed as multilayer interconnection. And, at the same time, wirings can be prevented from contacting each other, allowing no short circuit. Furthermore, as already described above, the method of the embodiment under consideration can prevent occurrences of wire breaking.

Accordingly, in the embodiment under consideration, the semiconductor device 100 with the higher packaging density can be manufactured, while preventing failures such as short circuit and wire breaking. And, in addition, the thus-manufactured semiconductor device 100 has its wiring exposed so that any poor connection can be easily found.

Further, by using a plurality of nozzles to drop ink, a plurality of wirings (wires) can be simultaneously formed, improving the productivity.

In the first to third embodiments described above, wirings and others formed on the semiconductor devices have been described as examples, and the three-dimensional structure is not particularly limited to those. Other examples of three-dimensional structures that can be formed include a micrometer-size gas sensor for a cantilever hydrogen gas sensor, cantilever and probe as well as an actuator to be used in a micromachine.

The method for forming a three-dimensional structure, the method for manufacturing a semiconductor device, and the semiconductor device according to the present invention have been described in details. However, the present invention is by no means limited to the above-described embodiments; various improvements and modifications can be made without departing from its gist of the present invention.

### Example 1

Inclined wires were formed directly onto a surface of a substrate by using the apparatus 10 for forming a three-dimensional structure shown in FIG. 1.

An inkjet head was utilized as an ejector. In particular, a head, DMC-11610 (product model number) for DMP2831, manufactured by FUJIFILM Dimatix, Inc. was used. NPS-J (trade name) manufactured by HARIMA CHEMICALS, INC. was used for the ink. The substrate was a quartz glass.

The inclined wires were formed at an ejection frequency of 5 Hz and an ejection rate of 5 m/sec., having a distance of 1.5 mm between the head and the substrate.

The temperature of the substrate was set to three different temperatures, 100° C., 120° C., and 140° C.

Various inclined wires were formed as varying a displacement amount of the ink arrival position, i.e., varying a shift amount of a droplet arrival position. Inclination angles of the thus-formed inclined wires were measured based on side view images of the wires photographed by a CCD camera.

FIG. 8 illustrates a relationship between the shift amount of a droplet arrival position and the inclination angle of an inclined wire formed at each substrate temperature. An inclined wire having an appropriate inclination angle could not be formed at the substrate temperature of 100° C. even though the shift amount of a droplet arrival position was varied. At this substrate temperature, drying rate of the ink did not follow the ink ejection frequency. That is, if an ink droplet previously ejected is not dried by the time the next ink droplet be ejected, formation of a wire would become unstable, thereby failing to form an inclined wire with a displacement (a shift amount) of a droplet arrival position of about 2 μm or more.

At each of the substrate temperatures of 120° C. and 140° C., on the other hand, the ink droplet previously ejected was dried by the time the next droplet was ejected. Hence, inclination angles of the inclined wires could be varied to be substantially linear with respect to shift amounts of a droplet arrival position.

And, when trying to form an inclined wire directly onto the substrate at a small inclination angle, the ink came in contact with the substrate and hence the inclined wire was hardly formed.

As described above, by regulating the substrate temperature, an inclined wire with a certain inclination angle depending on the displacement of a droplet arrival position could be formed.

### Example 2

Vertical wires with a height of 100 μm were formed on a surface of a substrate and thereafter inclined wires were formed on the surface of the substrate by using the apparatus 10 for forming a three-dimensional structure shown in FIG. 1. Here, the same inkjet head for the ejector used in Example 1 was used, and the wire-forming condition in Example 1 was also adopted.

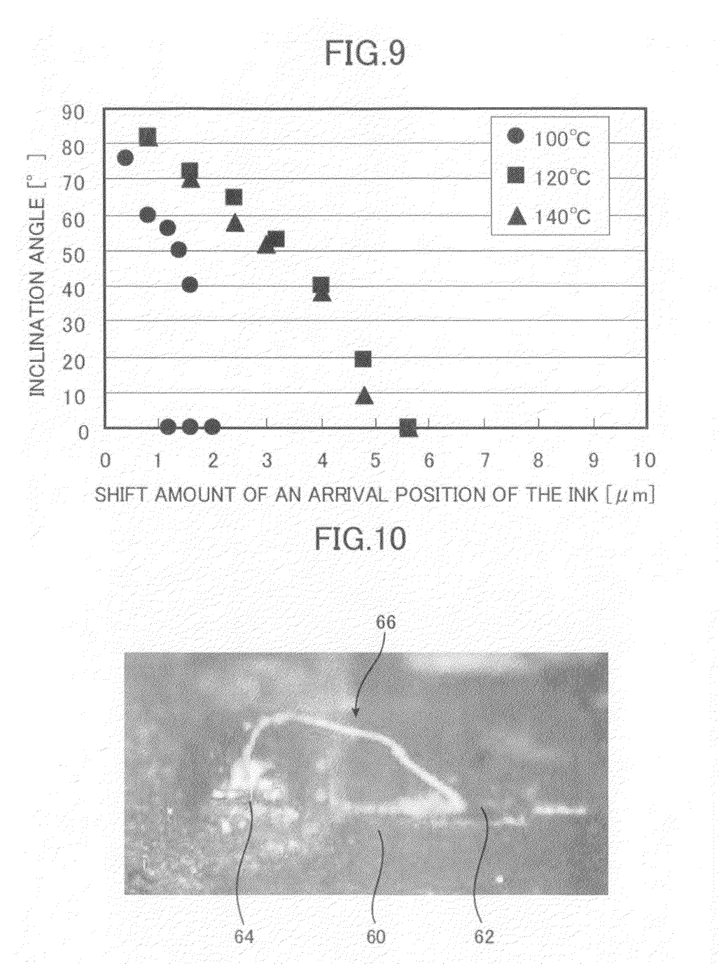

FIG. 9 illustrates a relationship between the shift amount of a droplet arrival position and an inclination angle of an inclined wire formed at each substrate temperature. An inclined wire having an appropriate inclination angle could not be formed at the substrate temperature of 100° C. even though the shift amount of a droplet arrival position was varied. At this substrate temperature, drying rate of the ink did not follow the ink ejection frequency. That is, if an ink droplet previously ejected is not dried by the time the next ink droplet be ejected, formation of a wire would become unstable, thereby failing to form an inclined wire with a displacement (a shift amount) of a droplet arrival position of about 2 μm or more.

At each of the substrate temperatures of 120° C. and 140° C., on the other hand, the ink droplet previously ejected was dried by the time the next droplet was ejected. Hence, inclination angles of the inclined wires could be varied to be substantially linear with respect to shift amounts of a droplet arrival position.

And, since the vertical wire was first formed, the ink did not come in contact with the substrate even at a small inclination angle, successfully forming the inclined wire of a small inclination angle.

As evidenced in Example 2, by regulating the substrate temperature, an inclined wire could be formed at a certain inclination angle with respect to the substrate surface, the inclination angle depending on the displacement of a droplet arrival position.

### Example 3

As shown in FIG. 10, a wiring 66 was formed to connect an electrode 62 provided on a substrate 60 and another electrode on an LED element 64 mounted on the substrate 60 by using the apparatus 10 for forming a three-dimensional structure illustrated in FIG. 1 and thereafter was subjected to a sintering process.

An inkjet head was utilized as an ejector. In particular, a head, DMC-11610 (product model number) for DMP2831, manufactured by FUJIFILM Dimatix, Inc. was used. NPS-J (trade name) manufactured by HARIMA CHEMICALS, INC. was used for the ink. A substrate was a ceramic substrate.

The wiring was formed under the condition of an ejection frequency of 1 Hz, a substrate temperature of 120° C., and a stage moving rate of 3.8 μm/sec.

In addition, the sintering process took place at a sintering temperature of 220° C. for one hour.

The sintering process was performed with a sintering furnace (Inert Oven DN610I, manufactured by Yamato Scientific Co., Ltd.).

The wiring 66 shown in FIG. 10 was of a sintered body as a result of the sintering process and in an arch-shape. As the LED element 64 was turned on, it actually lit so that electrical conduction through the wiring 66 was confirmed. Accordingly, the wiring of a sintered body was successfully formed in Example 3.

1. A method for forming a three-dimensional structure comprising:
a first step of dropping a liquid material containing a structure-forming material and a solvent onto a structure forming surface; and
a second step of drying at least a part of the solvent in the dropped liquid material to form a deposit layer on the structure forming surface,
wherein the first step and the second step are repeated while a dropping position of the liquid material is shifted such that a next droplet of the liquid material is dropped onto the deposit layer formed of the previously-dropped liquid material to repeatedly accumulate the deposit layers on the structure forming surface, thereby forming a three-dimensional structure having at least one inclination portion inclined with respect to the structure forming surface.

2. The method for forming a three-dimensional structure according to claim 1, wherein an inclination angle of the inclination portion with respect to the structure forming surface is adjusted by a shift amount of the dropping position of the liquid material.

3. The method for forming a three-dimensional structure according to claim 1, wherein the inclination angle of the inclination portion is 30° or larger.

4. The method for forming a three-dimensional structure according to claim 1, wherein the second step of drying the solvent in the dropped liquid material includes heating the structure forming surface.

5. The method for forming a three-dimensional structure according to claim 4, wherein the structure forming surface is heated to a temperature at which all of the solvent in the dropped liquid material dries out before a next droplet of the liquid material is dropped.

6. The method for forming a three-dimensional structure according to claim 1, wherein the inclination portion has at least one bending portion.

7. The method for forming a three-dimensional structure according to claim 1, wherein two or more inclination portions are joined at their respective ends.

8. The method for forming a three-dimensional structure according to claim 1, wherein the liquid material is dropped by one of an inkjet technique and a dispenser technique.

9. The method for forming a three-dimensional structure according to claim 1, wherein the structure-forming material is fine particles of one of a metal, an oxide of a metal, and an alloy of a metal.

10. The method for forming a three-dimensional structure according to claim 9, wherein the metal is selected from a group consisting of gold, silver, copper, platinum, nickel, palladium, and tin.

11. The method for forming a three-dimensional structure according to claim 1, wherein the structure-forming material develops conductive properties through sintering.

12. The method for forming a three-dimensional structure according to claim 1, further comprising a sintering process to sinter the inclination portion subsequent to formation of the inclination portion.

13. The method for forming a three-dimensional structure according to claim 12, wherein the inclination portion is formed to be longer by at least a length of heat shrinkage in the sintering process.

14. A method for manufacturing a semiconductor device comprising:
a step of mounting at least one semiconductor chip on a surface of a substrate having at least one first electrode thereon, each semiconductor chip being provided with at least one second electrode; and
a step of forming wiring between the at least one second electrode of each semiconductor chip and the at least one first electrode by a method for forming a three-dimensional structure comprising:
a first step of dropping a liquid material containing a structure-forming material and a solvent onto a structure forming surface; and
a second step of drying at least a part of the solvent in the dropped liquid material to form a deposit layer on the structure forming surface,
wherein the first step and the second step are repeated while a dropping position of the liquid material is shifted such that a next droplet of the liquid material is dropped onto the deposit layer formed of the previously-dropped liquid material to repeatedly accumulate the deposit layers on the structure forming surface, thereby forming a three-dimensional structure having at least one inclination portion inclined with respect to the structure forming surface.

15. A semiconductor device manufactured by a method comprising:
a step of mounting at least one semiconductor chip on a surface of a substrate having at least one first electrode thereon, each semiconductor chip being provided with at least one second electrode; and
a step of forming wiring between the at least one second electrode of each semiconductor chip and the at least one first electrode by a method for forming a three-dimensional structure comprising:
a first step of dropping a liquid material containing a structure-forming material and a solvent onto a structure forming surface; and
a second step of drying at least a part of the solvent in the dropped liquid material to form a deposit layer on the structure forming surface,
wherein the first step and the second step are repeated while a dropping position of the liquid material is shifted such that a next droplet of the liquid material is dropped onto the deposit layer formed of the previously-dropped liquid material to repeatedly accumulate the deposit layers on the structure forming surface, thereby forming a three-dimensional structure having at least one inclination portion inclined with respect to the structure forming surface.
